(19) United States
(12) Patent Application Publication
(10) Pub. No.: US 2022/0368286 A1
(43) Pub. Date: Nov. 17, 2022

(54) RF AMPLIFIER WITH A CASCODE DEVICE

(71) Applicant: Nordic Semiconductor ASA, Trondheim (NO)

(72) Inventors: Marko Pessa, Oulu (FI); David Zapata, Oulu (FI)

(73) Assignee: Nordic Semiconductor ASA, Trondheim (NO)

(21) Appl. No.: 17/745,479

(22) Filed: May 16, 2022

(30) Foreign Application Priority Data
May 14, 2021 (GB) 2106947.1

(51) Int. Cl. H03F 1/22; H03F 3/195; H03F 3/45; H03F 1/02

(52) U.S. Cl. CPC H03F 1/223; H03F 3/195; H03F 3/45179; H03F 1/0227; H03F 2200/267; H03F 2200/451

(57) ABSTRACT

An RF amplifier comprises a first ‘transconductance’ transistor (N_{CS}) arranged to receive an RF input voltage (RFIN) at its gate terminal. A second ‘cascode’ transistor (N_{CG}) has its source terminal connected to the drain terminal of the first transistor (N_{CS}) at a node (MID). A feedback circuit portion is configured to measure a node voltage at the node (MID), to determine an average of the node voltage, to compare said average node voltage to a predetermined reference voltage (V_{BCG}), and to generate a control voltage (CGGATE) dependent on the difference between the average node voltage and the predetermined reference voltage (V_{BCG}). The feedback circuit portion applies the control voltage (CGGATE) to the gate terminal of the second transistor (N_{CG}).

### CROSS-REFERENCE TO RELATED APPLICATION

This application claims priority from United Kingdom Patent Application No. 2106947.1, filed May 14, 2021, which application is incorporated herein by reference in its entirety.

### TECHNICAL FIELD

The present invention relates to a radio frequency (RF) amplifier with a cascode device, particularly though not exclusively in relation to an RF power amplifier, which provides improvements in compression behaviour while retaining good electrical reliability.

### BACKGROUND

Many modern electronic devices include one or more RF receivers, transmitters, and/or transceivers that provides for communication over a wireless interface. Examples of communications standards that make use of such devices include short-range communications protocols Bluetooth® and Bluetooth Low Energy® as well as cellular communications, such as the Long Term Evolution (LTE™) standard set out by 3GPP™. Such devices typically include one or more RF power amplifiers, which amplify an incoming signal to produce a signal of greater amplitude. Generally, such amplifiers include transconductance amplifiers, i.e. amplifiers that receive an RF input voltage and generate an RF output current.

Those skilled in the art will appreciate than an important design consideration for such amplifiers is its compression behaviour. An RF amplifier with steeper compression behaviour can be operated closer to saturation, i.e. with reduced back-off and consequently better efficiency can be obtained. However, it is typically extremely challenging to design high output power RF amplifier with nanoscale processes due to low operational and breakdown voltages of generally available devices. As a result, a ‘cascode’ device (or devices) is typically required to protect the actual gain device, where the gain is typically a transconductance gₘ.

However, the Applicant has appreciated that using traditional biasing techniques with cascode devices may cause early compression in the output power of the amplifier.

The Applicant has appreciated that the envelope of the received signal changes with time, particularly when working with different input powers. As outlined in further detail below with reference to FIGS. 1-3, this envelope has an associated DC (i.e. average) value and this can change the DC level at the ‘MID node’ between the transconductance gain (or ‘gₘ’) device and the cascode device. Thus when the RF input level is increased, the average current level from the gₘ device increases, as it is generally not biased to class-A but somewhere in class-AB operation. When the current level is increased, the voltage V_{gs_NCG} of the cascode device increases, which causes the voltage at the MID node to decrease. As the MID node voltage decreases, it modulates the transconductance in the gₘ device, eventually compressing and saturating the input voltage to output current transfer function, thereby causing the whole amplifier to compress too early.

### SUMMARY

When viewed from a first aspect, embodiments of the present invention provide an RF amplifier comprising:
a first transistor having respective first, second, and control terminals, wherein the first transistor is arranged to receive an RF input voltage at the control terminal thereof;
a second transistor having respective first, second, and control terminals, wherein the second terminal of the second transistor is connected to the first terminal of the first transistor at a node;
a feedback circuit portion configured to:
measure a node voltage at said node;
determine an average of said node voltage;
compare said average node voltage to a predetermined reference voltage;
generate a control voltage dependent on a difference between said average node voltage and predetermined reference voltage; and
apply said control voltage to the control terminal of the second transistor. Thus it will be appreciated that embodiments of the present invention provide an improved arrangement in which a feedback arrangement is used to measure the voltage at the node (interchangeably referred to throughout this disclosure as the ‘MID node’) and to adjust the voltage at the control terminal of the second (i.e. ‘cascode’) device so that the average voltage at the MID node is driven equal to the reference voltage. In this closed loop implementation, with increased input RF level, the gate of the cascode device is biased to a higher voltage level, leaving more operation voltage margin for the first transistor (i.e. the ‘gₘ’ device) and consequently mitigating and ideally avoiding early compression. The MID node average level may be kept at the reference level at all times, which may provide good protection for the gₘ device. The RF amplifier may, at least in some embodiments, comprise an RF power amplifier (PA). However, the principles of the present invention also apply to other RF amplifiers, including but not limited to an RF pre-amplifier (e.g. an RF pre-PA amplifier). The RF amplifier is referred to interchangeably herein as ‘the amplifier’.

The predetermined reference voltage is generally referred to throughout this disclosure as V_{BCG}.

The feedback circuit portion provides closed loop feedback to control the voltage at the MID node between the first terminal of the first transistor and the second terminal of the second transistor. In some embodiments, the feedback circuit portion comprises an operational amplifier configured to determine the difference between the average node voltage and the predetermined reference voltage and to generate the control voltage. In a particular set of such embodiments, the operational amplifier (or ‘op-amp’) has an inverting input and a non-inverting input, wherein the average node voltage is supplied to the inverting input, and wherein the predetermined reference voltage is supplied to the non-inverting input. It will be appreciated that, in general, an operational amplifier produces an output voltage proportional to the voltage at its non-inverting input minus the voltage at its inverting input, where the proportion is determined by the gain of the operational amplifier. In such embodiments, the control voltage is this output of the operational amplifier.

As outlined above, the feedback circuit portion averages the MID node voltage. This is done to remove the RF component of the voltage such that the gate of the second transistor is not modulated by the RF signal. In general, this may be achieved by passing the node voltage through a filter having a cut-off (or ‘corner’) frequency, where signals above this cut-off are significantly attenuated, i.e. a low-pass filter. This filter may, in some embodiments, be built in to a component of the feedback circuit portion, e.g. it may be an internal filter within an op-amp as discussed above.

However, in a particular set of embodiments, a filter network is connected between the node and the inverting input of the op-amp, the filter network comprising a resistor and a capacitor arranged such that:
a first terminal of the resistor is connected to the node;
a second terminal of the resistor is connected to a first terminal of the capacitor and to the inverting input of the operational amplifier; and
a second terminal of the capacitor is connected to a supply rail or ground. In such an arrangement, low frequency signals (i.e. the DC component) are passed to the inverting input of the op-amp, while high frequency signals (i.e. the RF component) are ‘shorted’ to the supply rail (which may be the negative supply rail) or ground via the capacitor.

In a set of potentially overlapping embodiments, a (second) filter network is connected between an input to the amplifier and the control terminal of the first transistor. This filter network may, in some such embodiments, be arranged to block unwanted DC signals from entering the amplifier and to only allow the RF signals of interest as an input. Thus the filter may be a high-pass filter with a properly selected cut-off frequency to permit the wanted RF signals into the amplifier, or may be a bandpass filter with a passband encompassing the bandwidth of interest. In a particular set of such embodiments, the second filter network comprises a second resistor and a second capacitor arranged such that:
a first terminal of the second capacitor is connected to the input of the amplifier;
a second terminal of the second capacitor is connected to a first terminal of the second resistor and to the control terminal of the first transistor; and
a second terminal of the second resistor is connected to a second predetermined reference voltage. This second predetermined reference voltage is generally referred to throughout this disclosure as V_{bcs}, and this voltage acts as a bias voltage for the transconductance device, biasing the device to some desired current level (e.g. drain current level in the case of a FET).

It will be appreciated that the term ‘second’ as used here in respect of the second filter network, second capacitor, and second resistor does not necessitate the existence of the ‘first’ filter network, capacitor, and/or resistor (i.e. those described in the preceding paragraph as sitting between the node and the inverting input of an op-amp). The present invention extends to embodiments having neither, one, or both such filter networks and associated components thereof, and the labels ‘first’ and ‘second’ are used only to refer to these elements individually.

Those skilled in the art will readily appreciate that transistors are generally arranged such that the current that flows between the first and second terminals is dependent on the state of the control terminal. There are a number of different transistor technologies, known in the art per se, which may be used to implement embodiments of the present invention. In some embodiments, the first and/or second transistors comprise field-effect-transistors (FETs). In particular, the first and/or second transistors may be metal-oxide-semiconductor FETs (MOSFETS). In a particular set of embodiments, the first and/or second transistors respectively may comprise an n-channel MOSFET.

Thus, for one or more of the transistors, the control terminal may be a gate terminal, the first terminal may be a drain terminal, and the second terminal may be a source terminal.

It will be appreciated, however, that the first and second transistors may comprise any suitable type of transistor, such as a heterojunction bipolar transistor (HBT), high-electron-mobility transistor (HEMT), insulated-gate bipolar transistor (IGBT). For example, the first and/or second transistors may comprise bipolar junction transistors (BJTs). As such, the control terminal may be a base terminal, the first terminal may be a collector terminal, and the second terminal may be an emitter terminal.

As outlined herein in respect of certain embodiments of the present invention, there may be provided one or more further transistors, each having respective first, second, and control terminals. Each of these may be a FET or a BJT, or any other suitable type of transistor. Arrangements are envisaged in which different transistors used in the device are different types of transistor to one another.

The second terminal of the first transistor may, in general, be connected to a predetermined voltage level or supply rail, which is typically the negative supply rail (i.e. ‘V_{SS}’) or ground.

The first terminal of the second transistor may, in general, be connected to a predetermined voltage level or supply rail, which is typically the positive supply rail (i.e. V_{DD}) via an impedance, to ensure proper generation of the (RF) output signal. In some embodiments, the impedance comprises an inductor connected between the first terminal of the second transistor and the positive supply rail. In particular, a first terminal of the inductor may be connected to the first terminal of the second transistor and a second terminal of the inductor may be connected to the positive supply rail. This inductor or ‘choke’ has a voltage drop across it approximately equal to the inductance of the inductor multiplied by the time derivative of the current through the first and second transistors. While the output voltage in such an arrangement theoretically swings around the positive supply rail voltage (i.e. alternating above and below the positive supply voltage V_{DD}), it will be appreciated that in reality the inductor may have an associated resistive loss, which will cause a slight drop in the average of the output voltage (i.e. causing the average of the output to drop below V_{DD}).

A third capacitor may, in some embodiments, be connected between the control terminal of the second transistor and a supply rail (e.g. the negative supply rail) or ground. This capacitor may act to control the gate impedance of the cascode device (i.e. the second transistor) at RF frequencies, i.e. to avoid gate modulation due to parasitic capacitances. This third capacitor can also be used as a loop stability compensation for the closed loop response.

The amplifier described hereinabove may be used in a single-ended configuration, i.e. the RF input voltage and RF output current are both single-ended. However, in some embodiments the amplifier is a differential amplifier. In some such embodiments, the amplifier further comprises:
a third transistor having respective first, second, and control terminals, wherein the RF input voltage is connected across the control terminals of the first and third transistors;
a fourth transistor having respective first, second, and control terminals, wherein the second terminal of the fourth transistor is connected to the first terminal of the third transistor at a second node;
wherein the feedback circuit portion is further configured to:
measure a second node voltage at said second node;
determine an average of a sum of the first and second node voltages to produce an average summed node voltage;
compare said average summed node voltage to the predetermined reference voltage;
generate the control voltage dependent on a difference between said average summed node voltage and predetermined reference voltage; and
apply said control voltage to the respective control terminals of the second and fourth transistors. It will be appreciated that the closed loop acts on the average of the sum of these node voltages.

In such embodiments, a differential RF output may be taken across the first terminals of the second and fourth transistors.

In some embodiments, multiple cascode devices may be ‘stacked’, wherein each cascode device may be controlled by an individual closed feedback loop, or may be controlled together with the same closed feedback loop that controls at least one another cascode device.

Thus in some embodiments, the amplifier further comprises a fifth transistor having respective first, second, and control terminals, wherein the second terminal of the fifth transistor is connected to the first terminal of the second transistor, and wherein the output of the RF amplifier is connected to the first terminal of the fifth transistor. One or more further transistors may be connected between the second terminal of the fifth transistor and the first terminal of the second transistor, such that said transistors are arranged such that the first terminal of each transistor is connected to the second terminal of the transistor above it.

In a particular set of embodiments in which the amplifier is a differential amplifier, a stack of cascode devices may be provided on each side of the differential amplifier. In other words, a sixth transistor having respective first, second, and control terminals, may be arranged such that the second terminal of the sixth transistor is connected to the first terminal of the fourth transistor. In such embodiments, a differential RF output may be taken across the first terminals of the fifth and sixth transistors. One or more further stacked cascode transistors may be connected between the fourth and sixth transistors in the same way as those optional further transistors discussed above that may be connected between the second and fifth transistors.

The stacked cascode devices may each be controlled by a respective dedicated feedback circuit portion, or a feedback circuit portion may control more than one (and potentially all) of the stacked cascode devices, i.e. the output of a feedback circuit portion (e.g. the output of the op-amp) may be connected to the control terminals of more than one cascode device. Where a single feedback circuit portion drives the control terminals of multiple stacked cascode devices, a potential divider may be used to divide the output voltage of the feedback circuit portion (e.g. the output of the op-amp) appropriately such that the control terminal of each of the stacked cascode devices is supplied with the desired proportion of the feedback circuit's output voltage.

It will be appreciated that the optional features described above with respect to various embodiments of the present invention may be combined together in any combination or permutation, as appropriate.

### BRIEF DESCRIPTION OF DRAWINGS

Certain embodiments of the invention will now be described, by way of non-limiting example only, with reference to the accompanying drawings in which:

FIG. 1 is a schematic diagram of a prior art amplifier;

FIGS. 2a and 2b are plots respectively showing the harmonic content of the MID-node voltage and the compressive behaviour of the power amplifier of FIG. 1;

FIGS. 3a and 3b are plots respectively showing an ideal rectified sine wave representing the drain current for different input drives and the harmonic content of the rectified sine wave;

FIG. 4 is a schematic diagram of an electronic device having an RF amplifier constructed from cascaded transconductance and transimpedance amplifier stages in accordance with an embodiment of the present invention;

FIG. 5 is a plot showing the waveform at the MID-node for two input drive levels with and without using the improvements of the present invention;

FIG. 6 is a plot showing the compression curve with and without using the improvements of the present invention;

FIG. 7 is a schematic diagram of a differential RF amplifier in accordance with another embodiment of the present invention; and

FIG. 8 is a schematic diagram of an RF amplifier using multiple stacked cascode devices in accordance with another embodiment of the present invention.

### DETAILED DESCRIPTION

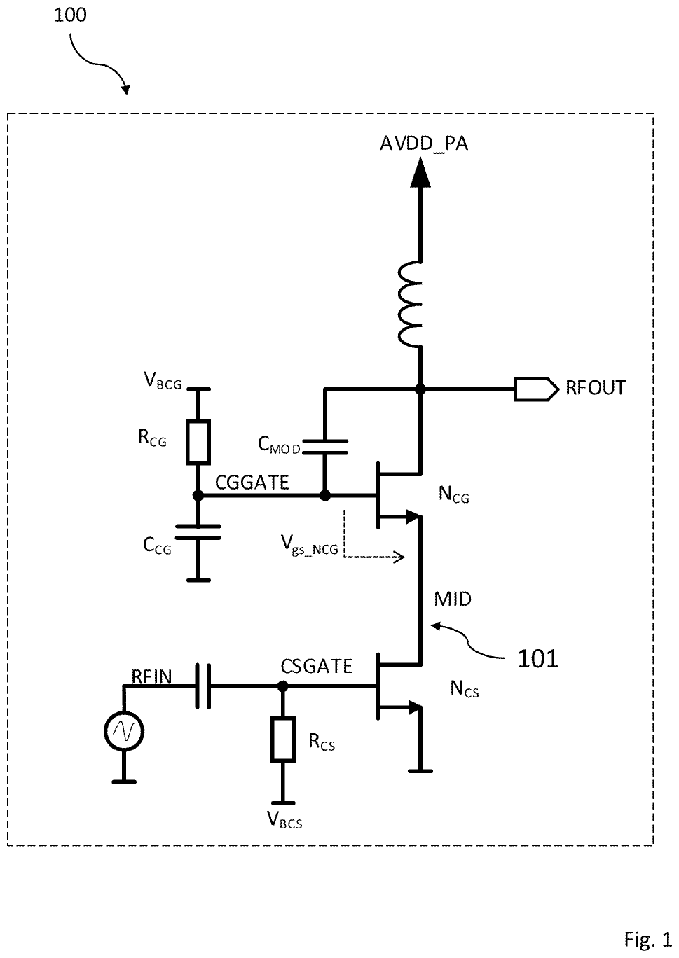

FIG. 1 shows a typical prior-art RF amplifier 100, known in the art per se. A transconductance gₘ device N_{CS} translates a received RF input voltage ‘RFIN’ to an RF output current ‘RFOUT’. Typically, this gₘ device N_{CS} is a short channel device because it needs to provide high transconductance in order to be efficient. However, short channel devices tend to have low breakdown voltages and thus often require cascode device for protection.

In the amplifier 100 of FIG. 1, a cascode device N_{CG} protects N_{CS} by controlling the average voltage level at the node 101 between them, labelled ‘MID’ (referred to herein as the ‘MID node’ 101). Depending on the voltage levels and output power requirements, more than one of these cascode devices may be stacked.

A voltage source V_{BCG} biases the cascode device N_{CG} via a resistor R_{CG}. A capacitor C_{CG} provides a small impedance path at RF frequencies to avoid or control capacitive modulation of the RF signal. A further capacitor C_{MOD} (which may be a physical capacitor or simply the parasitic capacitance from N_{CG} device) tends to modulate C_{GGATE} node, which can be alleviated or adjusted with the capacitor C_{CG}. If C_{GGATE} is allowed to be modulated with RF, it can be used to share the stress or excess voltage between cascode devices and the gₘ device N_{CS}. However, this tends to degrade the compression behaviour of the amplifier 100.

When the RF input level is increased, the average current level from the gₘ device N_{CS} increases, as it is generally not biased to class-A but somewhere in class-AB operation. When the current level is increased, the voltage V_{gs_NCG} of the cascode device N_{CG} increases, which causes the voltage at the MID node 101 to decrease. As the voltage at the MID node 101 decreases, it modulates the transconductance in the gₘ device N_{CS}, eventually compressing and saturating the input voltage to output current transfer function, thereby causing the whole amplifier 100 to compress too early.

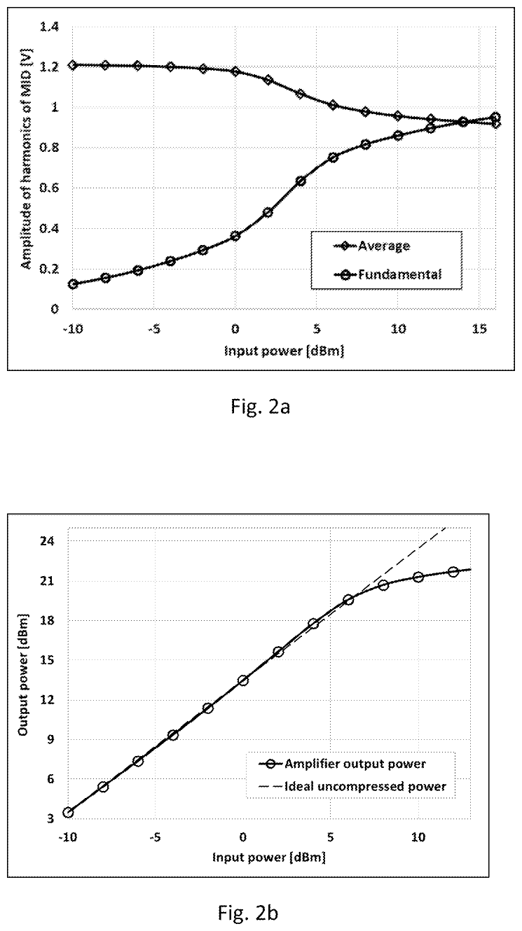

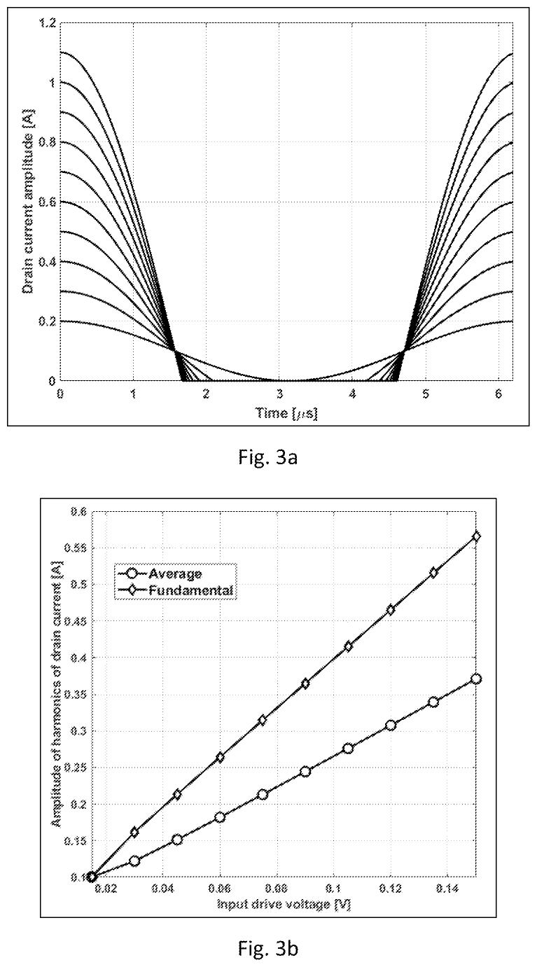

FIG. 2a shows the amplitude of the harmonics at the MID node 101 as a function of the input power. FIG. 2b shows the output power as a function of the input power. It can be seen from Figs. 2a and 2b that the DC component (i.e. average) of the voltage at the MID node 101 decreases with increased input drive, which contributes to the compression of the amplifier 100, and thus a drop in output power. As mentioned above, this is caused by the increase of the DC (i.e. average) level of the clipped drain current with increased input drive, which is illustrated in FIGS. 3a and 3b.

In particular, FIGS. 3a and 3b illustrate the harmonic content of a theoretical rectified sine wave whose amplitude is being constantly increased, simulating increased input drive of the amplifier 100. FIG. 3a shows the drain current amplitude as a function of time. In FIG. 3b, it can be seen that the amplitude of the harmonics of the drain current (both the average and the fundamental) increase as the input drive voltage is increased.

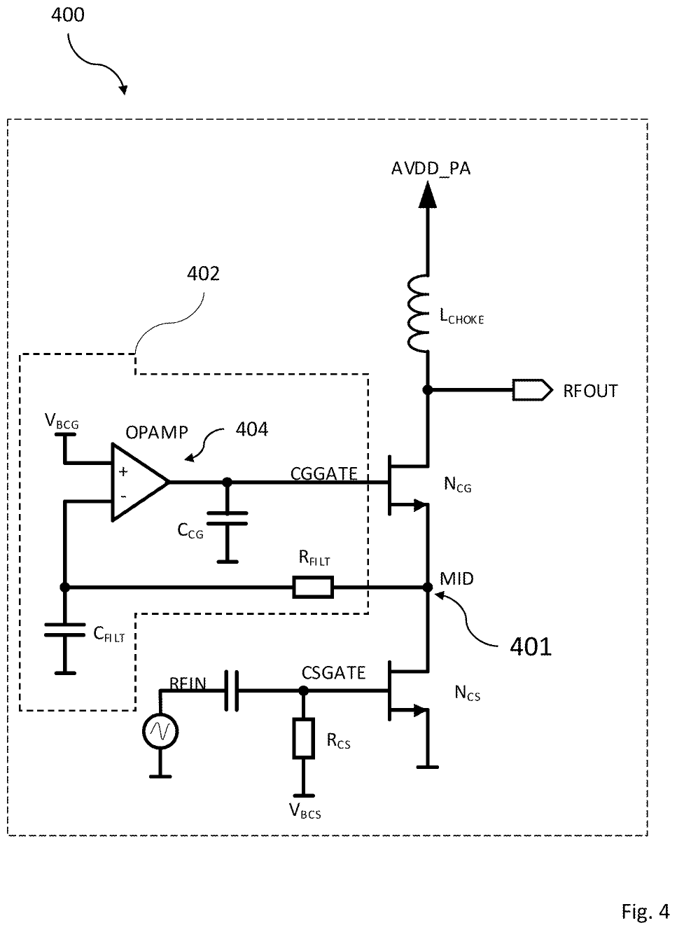

FIG. 4 is a schematic diagram of an RF amplifier 400 in accordance with an embodiment of the present invention. Here, a feedback circuit portion 402 including an op-amp 404 is used to measure the voltage at the MID-node 401 and adjust the voltage CGGATE applied to the gate terminal (i.e. control terminal) of the cascode device N_{CG}.

Specifically, the op-amp 404 is arranged such that its non-inverting input terminal is connected to V_{BCG} and such that its inverting input terminal is connected to the MID node via a low-pass filter constructed from a resistor R_{FILT} and a capacitor C_{FILT}This drives the average voltage at the MID node equal to the V_{BCG} voltage. As outlined in further detail below, the low-pass filter R_{FILT}, C_{FILT} acts to ‘average’ the voltage at the MID node such that RF frequency components are removed, while allowing the DC component (i.e. the average) of the MID node voltage to pass to the inverting input of the op-amp 404.

The op-amp 404 acts to compare the average voltage at the MID node 401 to the predetermined voltage V_{BCG} at the non-inverting input of the op-amp 404, and outputs a control voltage CGGATE that is proportional to the difference between them.

RF modulated signals such as those used in LTE® cellular communication systems may have varying envelope power, i.e. they have non-zero peak-to-average power ratio (PAPR). The filtering provided by R_{FILT} and C_{FILT} removes the RF component of the MID node voltage, leaving only the average component of the voltage at the MID node 401. In order for the closed loop to follow the RF envelope, the filter also preserves the slowly varying envelope component of the voltage at the MID node 401.

The capacitor C_{CG} connected to the gate terminal of the cascode device N_{CG} controls the cascode device gate impedance at RF frequencies, i.e. to avoid gate modulation due to parasitic capacitances. This capacitor C_{CG} can also be used as a loop stability compensation for the closed loop response.

Thus in this closed loop implementation, as the input RF level increases, CGGATE is biased to a higher voltage level leaving more operation voltage margin for the gₘ device N_{CS} and consequently avoiding early compression. As the average level of the MID node voltage is driven to V_{BCG} at all times, this also provides good protection for the gₘ device N_{CS}.

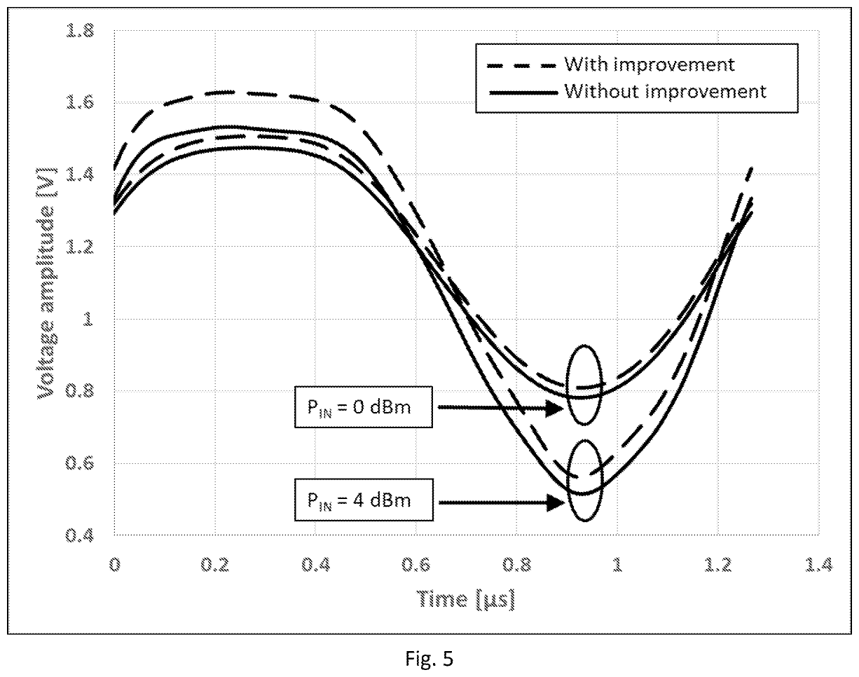

FIG. 5 shows the difference in voltage at the MID node 401 for two different input powers P_{IN}—at 0 dBm and 4 dBm. The solid lines illustrate the performance of a conventional amplifier without the improvement of the present invention, while the dashed lines illustrate performance of the RF power amplifier 400 having the improvement of the present invention. As can be seen in FIG. 5, when using this invention the voltage at the MID node 401 is not reduced as much, delaying the compression of the transconductance of the gₘ device N_{CS}.

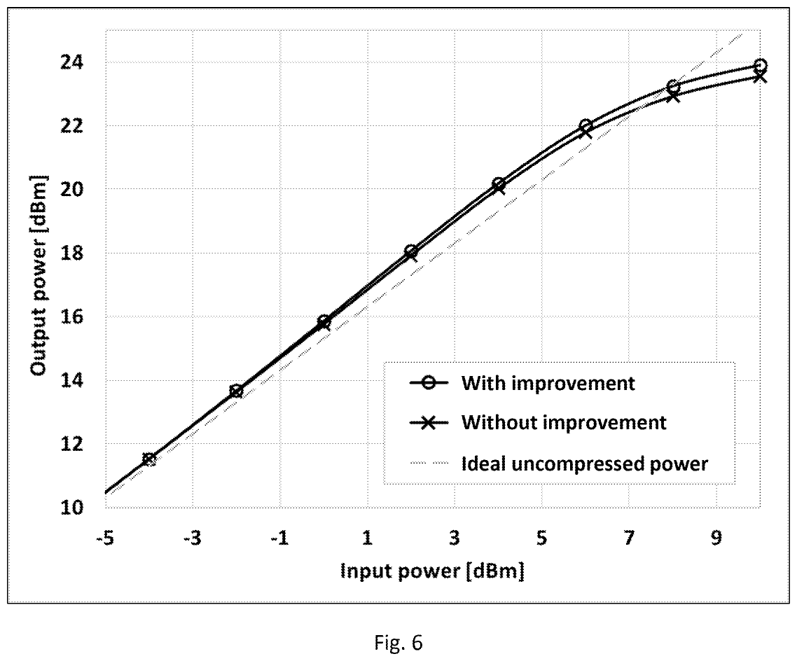

The effect of this invention in the compression behaviour of the RF amplifier 400 is presented in FIG. 6, where the solid line with cross-shaped markers illustrates the output power curve associated with a conventional amplifier and where the solid line with circular markers illustrates the output power curve associated with the RF amplifier having the improvement of the present invention. The dashed line illustrates ideal uncompressed power, which is a straight, diagonal line. It can be seen from FIG. 6 that the slope of the output power curve for the amplifier in accordance with the present invention is steeper than that of the conventional amplifier, increasing the 1 dB compression point of the amplifier.

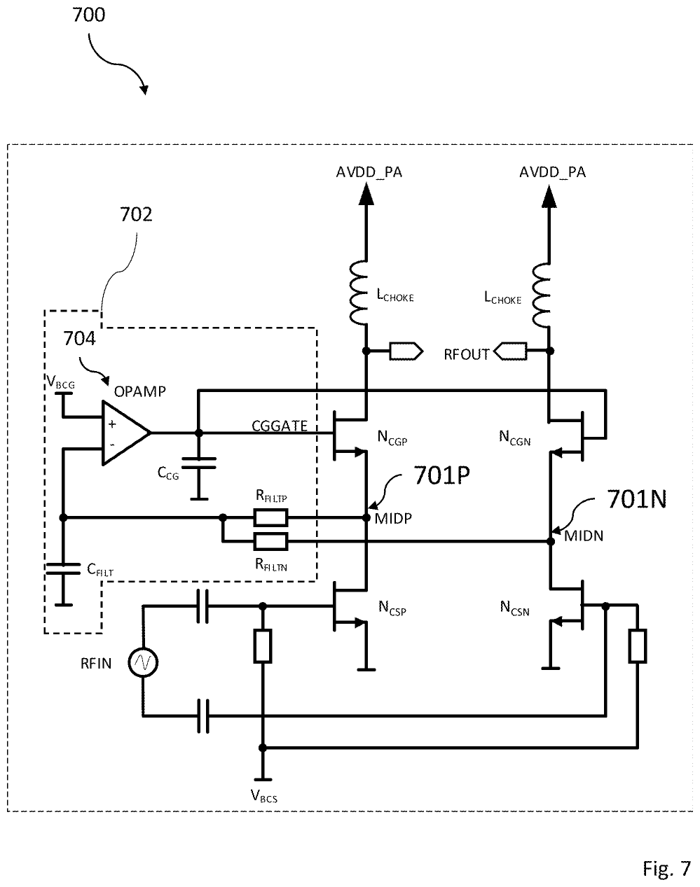

This invention can be applied also in differential implementations, where an embodiment of such a differential amplifier 700 is shown in FIG. 7. In the differential amplifier 700 of FIG. 7, there is a positive branch and a negative branch. The positive branch is constructed from a gₘ device N_{CSP} and a cascode device N_{CGP}. Similarly the negative branch is constructed from a gₘ device N_{CSN} and a cascode device N_{CGN} Each branch has a respective MID node 701P, 701N (labelled ‘MIDP’ and ‘MIDN’ respectively) between the gₘ and cascode devices of that branch.

Each of these branches is alike in function and structure to the stacked gₘ device N_{CS} and cascode device N_{CG} described previously with respect to FIG. 4, except now the RF input voltage RFIN is differential and is applied across the gate terminals of the positive and negative branch gₘ devices N_{CSP}, N_{CSN}; and the RF output voltage is taken across the drain terminals of the positive and negative branch cascode devices N_{CGP}, N_{CGN}.

In such an arrangement, a separate feedback circuit portion could be provided for each branch, or they could be controlled with the same closed loop feedback circuit portion. In the particular embodiment of FIG. 7, a single feedback circuit portion 701 is used for both branches, and is arranged such that the dedicated resistors R_{FILTP}, R_{FILTN} are respectively connected to the MIDP and MIDN nodes 701P, 701N at one terminal, and together at their other terminal, which are also connected to the inverting input of the op-amp 704. A filter capacitor C_{FILT} is connected between the inverting input of the op-amp 704 and ground or a supply rail (e.g. the negative supply rail), like in the arrangement of FIG. 4. The resistors R_{FILTP}, R_{FILTN} and capacitor C_{FILT} act as a low-pass filter, averaging the voltages at the MIDP and MIDN nodes 701P, 701N. Due to the arrangement of the resistors R_{FILTP}, R_{FILTN}, the voltages at the MIDP and MIDN nodes 701P, 701N are summed and averaged, i.e. equivalently the average voltages at the MIDP and MIDN nodes 701P, 701N are averaged.

The op-amp 704 compares the average voltage at the MIDP and MIDN nodes 701P, 701N to the reference voltage V_{BCG} and generates at its output a control voltage CGGATE that is proportional to the difference between them. This control voltage CGGATE is applied to the gate terminals of the cascode devices N_{CGP}, N_{CGN} in each of the positive and negative branches.

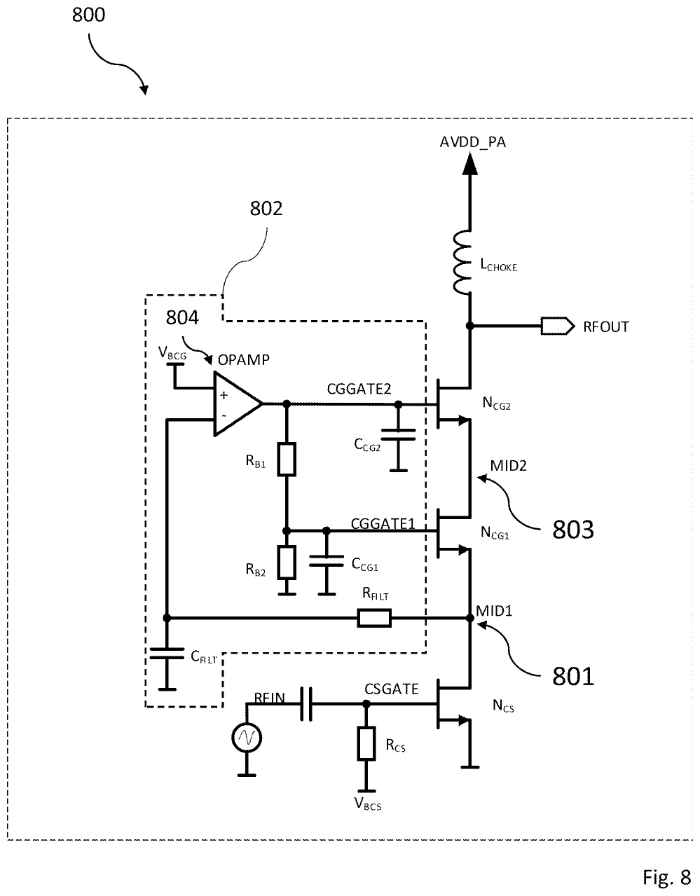

FIG. 8 is a schematic diagram of an amplifier 800 using multiple stacked cascode devices in accordance with another embodiment of the present invention. In this arrangement, an additional cascode device N_{CG2} is stacked on top of the first cascode device N_{CG1} (equivalent to the cascode device N_{CG} of FIG. 4), such that the source terminal of the second cascode device N_{CG2} is connected to the drain terminal of the first cascode device N_{CG1} at a second mid node 803 (or ‘MID2’) and the drain terminal of the second cascode device N_{CG2} is connected to AVDD_PA via the choke inductor L_{CHOKE} (rather than the choke inductor L_{CHOKE} being connected to the drain terminal of the first cascode device N_{CG1} as per FIG. 4). The RF output RFOUT is now taken from the drain terminal of the second cascode device N_{CG2}, rather than from the drain terminal of the first cascode device N_{CG1}.

With case of a stack of two or more cascode devices, there could be a separate closed loop for each device, or there could be a common control as is the case in the amplifier 800 of FIG. 8 (or some combination of both).

In the common control approach shown in FIG. 8, the feedback circuit portion 802 measures the voltage at the MID1 node 801 (i.e. between the drain terminal of the gₘ device N_{CS} and the source terminal of the first cascode device N_{CG1}), and averages it using the low-pass filter R_{FILT}, C_{FILT} in the same manner described previously. This average MID1 node voltage is compared to the reference level V_{BCG} by the op-amp 804, which produces a voltage at its output proportional to the difference between them.

A potential divider constructed from R_{B1} and R_{B2} divides the output of the op-amp 804 and distributes control voltages CGGATE1 and CGGATE2 to the gate terminals of the first cascode device N_{CG1} and second cascode device N_{CG2} respectively, where these are dependent on the ratio of R_{B1} and R_{B2}.

The techniques shown in FIGS. 7 and 8 may, of course, be combined such that the differential amplifier has multiple stacked cascode devices on each of its positive and negative branches.

Thus it will be appreciated that embodiments of the present invention provide an improved RF amplifier which utilises closed loop feedback to measure the voltage at the MID node and to drive the average voltage at the MID node toward a predetermined reference voltage. This arrangement may provide improved operation voltage margins for the gₘ device and avoid early compression.

While specific embodiments of the present invention have been described in detail, it will be appreciated by those skilled in the art that the embodiments described in detail are not limiting on the scope of the claimed invention.

1. An RF amplifier comprising:
a first transistor having respective first, second, and control terminals, wherein the first transistor is arranged to receive an RF input voltage at the control terminal thereof;
a second transistor having respective first, second, and control terminals, wherein the second terminal of the second transistor is connected to the first terminal of the first transistor at a node;
a feedback circuit portion configured to:
measure a node voltage at said node;
determine an average of said node voltage;
compare said average node voltage to a predetermined reference voltage;
generate a control voltage dependent on a difference between said average node voltage and predetermined reference voltage; and
apply said control voltage to the control terminal of the second transistor.

2. The RF amplifier of claim 1, wherein the feedback circuit portion comprises an operational amplifier configured to determine the difference between the average node voltage and the predetermined reference voltage and to generate the control voltage.

3. The RF amplifier of claim 2, wherein the operational amplifier has an inverting input and a non-inverting input, wherein the average node voltage is supplied to the inverting input, and wherein the predetermined reference voltage is supplied to the non-inverting input.

4. The RF amplifier of claim 1, further comprising a filter network connected between the node and the inverting input of the op-amp, the filter network comprising a resistor and a capacitor arranged such that:
a first terminal of the resistor is connected to the node;
a second terminal of the resistor is connected to a first terminal of the capacitor and to the inverting input of the operational amplifier; and
a second terminal of the capacitor is connected to a supply rail or ground.

5. The RF amplifier of claim 1, wherein a second filter network is connected between an input to the amplifier and the control terminal of the first transistor, wherein the second filter network comprises a second resistor and a second capacitor arranged such that:
a first terminal of the second capacitor is connected to the input of the amplifier;
a second terminal of the second capacitor is connected to a first terminal of the second resistor and to the control terminal of the first transistor; and
a second terminal of the second resistor is connected to a second predetermined reference voltage.

6. The RF amplifier of claim 1, wherein the second terminal of the first transistor is connected to a first predetermined voltage level or supply rail.

7. The RF amplifier of claim 1, wherein the first terminal of the second transistor is connected to a second predetermined voltage level or supply rail via an impedance, wherein the first terminal of the second transistor is connected to a positive supply rail.

8. The RF amplifier of claim 7, wherein the impedance comprises an inductor connected between the first terminal of the second transistor and the second predetermined voltage level or supply rail.

9. The RF amplifier of claim 1, comprising a third capacitor connected between the control terminal of the second transistor and a supply rail or ground.

10. The RF amplifier of claim 1, further comprising:
a third transistor having respective first, second, and control terminals, wherein the RF input voltage is connected across the control terminals of the first and third transistors;
a fourth transistor having respective first, second, and control terminals, wherein the second terminal of the fourth transistor is connected to the first terminal of the third transistor at a second node;
wherein the feedback circuit portion is further configured to:
measure a second node voltage at said second node;
determine an average of a sum of the first and second node voltages to produce an average summed node voltage;
compare said average summed node voltage to the predetermined reference voltage;
generate the control voltage dependent on a difference between said average summed node voltage and predetermined reference voltage; and
apply said control voltage to the respective control terminals of the second and fourth transistors.

11. The RF amplifier of claim 10, wherein a differential RF output is taken across the first terminals of the second and fourth transistors.

12. The RF amplifier of claim 1, further comprising a fifth transistor having respective first, second, and control terminals, wherein the second terminal of the fifth transistor is connected to the first terminal of the second transistor, and wherein the output of the RF amplifier is connected to the first terminal of the fifth transistor.

13. The RF amplifier of claim 12, wherein the feedback circuit portion is configured to apply the control voltage to the respective control terminal of the fifth transistor.

14. The RF amplifier of claim 12, further comprising one or more further transistors connected between the second terminal of the fifth transistor and the first terminal of the second transistor, such that said transistors are arranged such that the first terminal of each transistor is connected to the second terminal of the transistor above it.

15. The RF amplifier of claim 14, wherein the feedback circuit portion is configured to apply the control voltage to at least one of the one or more further transistors connected between the fifth transistor and the second transistor.

16. The RF amplifier of claim 10, further comprising a sixth transistor having respective first, second, and control terminals, wherein the second terminal of the sixth transistor is connected to the first terminal of the fourth transistor.

17. The RF amplifier of claim 16, wherein the feedback circuit portion is configured to apply the control voltage to the respective control terminal of the sixth transistor.

18. The RF amplifier of claim 16, wherein a differential RF output is taken across the first terminals of the fifth and sixth transistors.

19. The RF amplifier of claim 16, further comprising one or more further transistors connected between the second terminal of the sixth transistor and the first terminal of the fourth transistor, such that said transistors are arranged such that the first terminal of each transistor is connected to the second terminal of the transistor above it.

20. The RF amplifier of claim 19, wherein the feedback circuit portion is configured to apply the control voltage to at least one of the one or more further transistors connected between the sixth transistor and the fourth transistor.

21. The RF amplifier of claim 1, wherein the RF amplifier is an RF power amplifier.
